(19) United States
(12) Patent Application Publication
(10) Pub. No.: US 2014/0020746 A1
(43) Pub. Date: Jan. 23, 2014

(54) METAL CONTACT SCHEME FOR SOLAR CELLS

(71) Applicants: Alison Joan Lennon, Rozelle (AU); Pei Hsuan Lu, Rockdale (AU); Yang Chen, Rochester, NY (US)

(72) Inventors: Alison Joan Lennon, Rozelle (AU); Pei Hsuan Lu, Rockdale (AU); Yang Chen, Rochester, NY (US)

(73) Assignee: NewSouth Innovations Pty Limited, UNSW, Sydney (AU)

(21) Appl. No.: 13/805,403

(22) PCT Filed: May 17, 2011
(86) PCT No.: PCT/AU2011/000586

§ 371 Date: Sep. 5, 2013

(30) Foreign Application Priority Data
Jul. 2, 2010 (AU) 2010902964

(51) Int. Cl. H01L 31/02

(52) U.S. Cl. CPC H01L 31/02021
USPC 136/256; 438/83

(57) ABSTRACT

A method of forming point metal electrical contacts to a semiconductor surface of a semiconductor device is provided. In a first step a first metal layer is formed over the semiconductor surface. The first metal layer is then anodised to create a porous metal-oxide layer formed over the semiconductor surface. The pores in the porous metal-oxide layer will thus form an array of openings in the porous metal-oxide layer. A contact metal layer is then formed over the porous metal-oxide layer such that parts of the contact metal layer extend into openings of the array of openings. The contact metal layer electrically contacts the semiconductor surface through the array of openings in the porous metal-oxide layer. A dielectric layer may optionally be formed over the semiconductor surface and the porous metal-oxide layer the formed over the dielectric layer and the contact metal then contacts the semiconductor surface through the dielectric layer.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### TECHNICAL FIELD OF THE INVENTION

The present invention relates generally to the field of device fabrication and, in particular, to the formation of rear point contacts for solar cell devices, particularly silicon solar cell devices.

### BACKGROUND OF THE INVENTION

The fabrication of solar cell semiconductor devices typically involves the formation of metal contacts to a p-n junction device. The semiconductor material (e.g., silicon) absorbs light and generates electron and hole carriers which can then be separated by the p-n junction in the device. Majority carriers (e.g., electrons in n-type semiconductor material) are collected by the metal contacts which are formed to both the p-type and n-type material of the device. In standard screen-printed silicon solar cells, the n-type metal contacts (which collect electrons) are formed by screen printing and subsequently firing a silver paste M a grid pattern over the front (illuminated side) of the wafer-based device. The p-type contact is formed by screen-printing the entire rear p-type surface of the device with an aluminium paste. This paste, when fired at temperatures of 780-870° C., forms a back-surface field (BSF) which reduces the recombination of the electron minority carriers (in p type material) at the silicon-metal interface and enables the collection of the hole majority carriers.

Screen-printed silicon solar cells have been industrially produced for 25-30 years with continued improvements driving efficiencies towards 17-18% and 16-17% mono-crystalline .and multi-crystalline wafer substrates, respectively. However, these efficiencies are still substantially less than the values achieved by laboratory-fabricated solar cells. For example, the world record for the highest efficiency single junction silicon solar cell is 25% obtained by the University of New South Wales in 1999. One of the reasons why these laboratory-fabricated solar cells achieve the higher efficiencies is that they typically use point metal contacts to make contact with the silicon on the rear surface. In the case of the world-record Passivated Emitter Rear Locally-Diffused (PERL) cell fabricated at the University of New South Wales, small openings of dimension 10 μm×10 μm were made in a rear-side silicon dioxide dielectric layer. Metal was then evaporated through these small-area point size openings to form p-type metal contacts to the cell.

By limiting the total area of the metal silicon interface, recombination of minority and majority carriers can be significantly reduced resulting in higher open circuit voltages for the resulting device. The performance of the PERL cell was further enhanced by performing boron diffusion through the contact openings, before metallisation, to create heavily-doped regions at the base of the openings. These heavily-doped regions further reduce carrier recombination and decrease the contact resistance resulting in reduced series resistance in the final device.

Most PERL cells are fabricated using p-type wafers in which a p-n junction is formed on the front (illuminated side) by performing a phosphorus solid-state diffusion process. The fabrication process requires the use of high-quality float-zone (FZ) wafers in which the minority carrier lifetimes can be as high as 500 μs in 1 Ωcm p-type wafers. Furthermore thick wafers are typically used to ensure excellent absorption of incoming light. Electrons are collected via a narrow metal grid formed on the front-side of the cell, and holes are collected by the point contacts on the rear surface. In order to limit the spreading resistance experienced as the carriers are collected from hemispherical regions of p-type silicon above the contact openings, it can be shown that it is advantageous to have the point contacts located as close as possible to each other. Furthermore, it is desirable to minimise as far as practicable the total metal-silicon interface area in order to keep the recombination of carriers to a minimum. In the world-record efficiency PERL cell, the point contacts were spaced 250 μm apart.

The fact that most industrial processes for manufacturing silicon solar cells still rely on using an entire rear surface metal contact, as described above for the screen-printed cell, demonstrates the practical difficulty in achieving closely-spaced small-area point contacts for rear contact schemes. For the PERL cell, the point contacts were fabricated using photolithography, which is considered far too expensive to implement for commercial production. Laser-firing of point contacts though an evaporated aluminium layer has been trialled, however this process can result in material damage to the silicon and thus lower voltages. Also, since a laser is essentially a continuous stream device, the firing of point contacts requires some form of masking or shuttering. Furthermore, if the point contacts are to be spaced close to each other then it is time-consuming to scan across an entire rear surface for the patterning process. Inkjet etching of point contact has also been trialled. Although this approach does not typically result in any damage to the photoactive material it suffers from the same processing throughput issues as the laser-fired contacts. Consequently, the formation of patterns of point contacts on the rear surface of silicon solar cells for the purpose of metal contacting is still an active area of research for silicon solar cell fabrication.

### SUMMARY

In a first aspect, a method of forming point metal electrical contacts to a semiconductor surface of a semiconductor device is provided, the method comprising:

i) forming a first metal layer over the semiconductor surface;

ii) anodising the first metal layer to create a porous oxide layer over the semiconductor surface whereby pores in the porous metal-oxide layer form an array of openings through the porous metal-oxide layer;

iii) forming a contact metal layer over the porous metal-oxide layer and parts thereof extending into openings of the array of openings such that the contact metal layer electrically contacts the semiconductor surface through the array of openings in the porous metal-oxide layer.

In a second aspect, a semiconductor device is provided having a semiconductor surface on which an electrical contact is formed, the device comprising:

i) a porous metal-oxide layer formed over the semiconductor surface whereby pores in the porous metal-oxide layer form an array of openings through the porous metal-oxide layer;

ii) a contact metal layer formed over the porous metal-oxide layer and parts thereof extending into openings of the array of openings such that the contact metal layer makes electrical contact to the semiconductor surface through the array of openings in the porous metal-oxide layer to form the electrical contact.

In one embodiment the first metal layer is formed on the semiconductor surface, such that the porous oxide layer is in contact with the semiconductor surface after sintering.

However an intervening dielectric layer may be optionally formed over the semiconductor surface before the formation of the first metal layer whereby after the oxidation of the first metal layer, the dielectric layer is interposed between the porous metal-oxide layer and the semiconductor surface.

According to a third aspect, a method of forming point metal electrical contacts to a semiconductor surface of a semiconductor device is provided, the method comprising:
i) forming a dielectric layer on the semiconductor surface:
ii) forming a first metal layer over the dielectric layer;
iii) anodising the first metal layer to create a porous metal-oxide layer formed over the dielectric layer whereby pores in the porous, metal-oxide layer form an array of openings in the metal-oxide layer;
iv) forming a contact metal layer over the porous metal-oxide layer; and
v) heating the contact metal layer such that parts of the contact metal layer are driven through the dielectric layer to make electrically contact the semiconductor surface through the array of openings in the metal-oxide layer and the dielectric layer.

According to a third aspect, a semiconductor device, is provided having a semiconductor surface on which an electrical contact is formed, the device comprising:
i) a dielectric layer formed over the semiconductor surface;
ii) a porous metal-oxide layer formed over the dielectric layer whereby pores in the porous metal-oxide layer form an array of openings through the porous metal-oxide layer;
iii) a contact metal layer formed over the porous metal-oxide layer such that the contact metal layer electrically contacts the semiconductor surface through the array of openings in the porous metal-oxide layer and the dielectric layer to form the electrical contact.

Embodiments of the invention will preferably be based on silicon semiconductor technology and the dielectric layer will preferably comprise SiO2, SiNx, SiONx, SiC, Al₂O₃ or a combination of two or more thereof. The dielectric layer thickness may be in a range of 10-85 nm or 10-20 nm, or 20-20 nm, or 30-40 nm, or 40-50 nm, or 50-60 nm, or 60-70 nm, or 70-80 nm, or 80-85 nm.

The dielectric layer may be formed by PECVD followed by a forming gas anneal.

The semiconductor surface will preferably be textured. The texturing may be to a depth of 1-8 μm or 2-5 μm or 1-2 μm or 2-3 μm or 3-4 μm or 4-5 μm or 5-6 μm or 6-7 μm or 7-8 μm.

The heating of the metal contact layer will preferably be controlled to limit contact of the contact metal layer with the semiconductor surface to Only through those pores located at or adjacent to peaks or ridges of the texturing of the semiconductor surface.

The first metal layer is preferably composed of aluminium such that the metal-oxide layer is an aluminium oxide layer, however other metals that can undergo an anodic process include titanium, zinc, magnesium, niobium, and tantalum. The first metal layer is preferably sintered before being anodised.

The contact metal layer is preferably heated after its formation whereby the contact metal is diffused into the semiconductor surface. When a dielectric layer is interposed between the porous metal-oxide layer and the semiconductor surface, the contact metal layer is heated to Cause metal of the contact metal layer at a surface of the dielectric layer in at least some of the openings of the array of openings in the porous metal-oxide layer to be driven through the dielectric layer to contact the semiconductor surface.

The porous metal-oxide layer is preferably etched prior to forming the contact metal layer to enlarge the pores forming the array of openings through the porous metal-oxide layer.

The anodised layer may be etched further before application of the contact metal layer to ensure that any barrier layer oxide is removed from the semiconductor surface at the base of each of the openings of the array of openings through the porous metal-oxide layer.

The first metal layer may be pre-processed to cause the,pores which result from the anodising step to preferentially form in selected locations. The pre-processing may comprise point-wise deposition of a fluid which creates a defect, indentation or weakness at each of the desired locations. The fluid may be deposited using an inkjet or aerosol jet printer. For example an etchant might be deposited to form depressions in the first metal layer at desired locations of the pores. Alternatively the surface of the first metal layer might be impressed with a die which creates dimples at each of the desired locations.

The parameters of the anodizing step are selected to achieve an average pore spacing which may be typically less than 500 μm, but generally less than 200 μm and preferably 100 μm or less.

Acids used in the anodisation process may include sulphuric acid, oxalic acid, phosphoric acid, or combinations of these used together or serially. For example the acid used may be 0.3-1.5M sulphuric acid and 1˜10% (wt/wt) phosphoric acid or the acid used may be 0.3M sulphuric acid. The deposited first metal layer may be anodised for 3-30 mins or 3-4 mins or 4-5 mins or 5-6 mins or 6-7 mins or 7-8 mins or 8-9 mins or 9-10 mins or 10-11 mins or 11-12 mins or 12-13 mins or 13-14 mins or 14-15 mins or 15-16 mins or 16-17 mins or 17-18 mins or 18-19 mins or 19-20 mins or 20-21 mins or 21-22 mins or 22-23 mins or 23-24 ruins or 24-25 mins. or 25-26 mins or 26-27 mins or 27-28 mins or 28-29 mins or 29-30 mins.

The first metal may be deposited by sputtering or more preferably using a thermal evaporation process. The thickness of the first metal layer and the subsequent porous metal-oxide layer may be in the range of 0.2-1.0 μm or 0.2-0.5 μm or 0.1-0.2 μm or 0.2-0.3 μm or 0.3-0.4 μm or 0.4-0.5 μm or 0.5-0.6 μm or 0.6-0.7 μm or 0.7-0.8 μm or 0.8-0.9 μm or 0.9-1.05 μm., and preferably between 0.2 and 0.5 μm. The deposited first metal layer is preferably sintered for 25-35 mins (nominally 30 min) at 350-450° C. (nominally 400° C.) prior to anodisation. After anodizing, the resulting porous metal oxide layer will have a thickness in the range of 0.2-1.0 μm or 0.2-0.5 μm or 0.1-0.2 μm or 0.2-0.3 μm or 0.3-0.4 μm or 0.4-0.5 μm or 0.5-0.6 μm or 0.6-0.7 μm or 0.7-0.8 μm or 0.8-0.9 μm or 0.9-1.0 μm.

Preferably the etching of the anodised first metal layer performed after the anodising step is performed until the pores are at least 200 or 250 nm in diameter and preferably in the range of 450-550 nm in diameter.

Finally, a contact metal layer, such as a layer of aluminium or aluminium alloy, may be deposited into the pores and over the entire rear surface of the porous metal-oxide layer possibly using methods such as sputtering and e-beam evaporation or screen printing, but preferably using thermal evaporation. The deposition of the contact layer will fill the pores in the insulating metal oxide layer and then the metal layer will preferably extend over the entire rear surface of the oxide layer to form the rear electrode for the solar cell. The thickness of the contact metal layer may be in the range of 1-4 μm or 1-2 μm or 2-3 μm or 3-4 μm between the pores, and preferably in the range of 1-2 μm. After deposition the deposited contact metal may be sintered at a temperatures ranging from 440° C. to a temperature above the metal-semiconductor eutectic temperature (577° C. for aluminium-silicon) or from 400-650° C. or 400-500° C. or 400-450° C. or 450-500° C. or 500-550° C. or 550-600° C. or 600-650° C. In one method, the deposited contact metal may be sintered at a temperature in the range of 445-455° C. for 10-15 mins or 1-2 mins or 2-3 mins or 3-4 mins or 4-5 mins or 5-6 mins or 6-7 mins or 7-8 mins or 8-9 mins or 9-10 mins or 10-11 mins or 11-12 mins or 12-13 mins or 13-14 mins or 14-15 mins. Alternatively, the deposited contact metal may be sintered at a temperature higher than the metal-semiconductor eutectic temperature (577° C. for aluminium-silicon) such that a metal-semiconductor alloy is formed at the base of the pores.

Alternatively, the rear contacts can be formed using other metallisation approaches such as metal plating, using metals such as nickel, copper, tin and/or silver. Plating may be by electroless plating or electroplating.

The step of heating of the contact metal layer may comprises firing of the contact metal layer at a peak temperature in the range of 650°-820° C. or 650°-670° C. or 670°-690° C. or 690°-710° C. or 710°-730° C. or 730°-750° C. or 750°-770° C. or 770°-790° C. or 790°-810° C. or 810°-820° C. (and more preferably at 680° C.) for less than 60 seconds or for 1-2 seconds, or 2-3 seconds, or 3-4 seconds, or 4-5 seconds, or 5-6 seconds, or 6-7 seconds, or 7-8 seconds, or 8-9 seconds, or 9-10 seconds, or 10-12 seconds, or 12-15 seconds, or 15-20 seconds, or 20-25 seconds, or 25-30 seconds, or 30-35 seconds, or 35-40 seconds, or 40-45 seconds, or 45-50 seconds, or 50-55 seconds, or 55-60 seconds at the peak temperature.

In a further alternative, the semiconductor surface may be exposed to dopant atoms (boron for p type material—e.g., boron tribromide or phosphorus for n type material—e.g. POCl₃) prior, to the final metallisation step or the entire rear semiconductor surface may be exposed to dopants (e.g., aluminium or boron for p-type material), before the anodisation step such that metal subsequently deposited or plated through the openings would contact heavily-doped semiconductor material.

### BRIEF DESCRIPTION OF THE DRAWINGS

Embodiments of a solar cell rear contact and its method of formation will now be described, by way of example, with reference to the accompanying drawings in which:

FIG. 1 is a diagrammatic illustration of a solar cell with a rear (non-illuminated) surface contact formed as a point metal contact structure formed through a porous dielectric layer;

FIG. 2 graphically represents a relationship between rear contact spacing and spreading resistance;

FIGS. 3a & 3b are:
a. a diagrammatic front view of a solar cell in an anodising tank, and
b. a diagrammatic bottom view of the solar cell through an anode electrode on which it is sitting;

FIG. 4 is a diagrammatic illustration of a solar cell with a rear (non-illuminated) surface contact formed as a point metal contact structure formed through a porous dielectric layer and an intervening dielectric layer;

FIG. 5 diagrammatic illustration of a porous dielectric material (i.e. anodized aluminium);

FIGS. 6a & 6b diagrammatically illustrate fabricated test structures.

FIG. 7 is a diagrammatic illustration of a textured solar cell with a rear (non-illuminated) surface contact formed as a point metal contact structure including an additional oxide layer intervening between the porous oxide metal-oxide layer and the substrate.

### DETAILED DESCRIPTION OF EMBODIMENTS

A new method of forming point metal contacts to a solar cell has been developed which has the potential to reduce the cost of providing high performance rear contacts. Unlike previously-described approaches which involve deterministic patterning of a dielectric layer to form an array of openings, the proposed method uses properties of an anodised metal film to form a passivating dielectric layer complete with an array of pores which can act as the openings for metal contacts. In other words, it is unique in that the dielectric film and the array of openings are formed in a single process. The pores may be self ordered or their location may be influenced by pre-processing. Metal contacts can then be formed to the underlying photoactive material by evaporating a further layer of metal such that the metal deposits both in the pores and on the entire rear surface of the anodised metal thus forming a rear electrode for the solar cell which only contacts the silicon via the openings in the passivating dielectric layer.

The spacing between pores (openings) formed can be controlled by varying the composition and concentration of the electrolyte used in the anodisation process. The size of the pores can be increased from their initial (anodised) size by immersing the anodised substrate in an aluminium oxide etchant in a post-anodisation step. The spacing and size of the formed pores (openings) can be further controlled/varied by performing multiple sequential anodisation steps, with each individual anodisation process potentially using a different electrolyte composition.

The chemical properties of the dielectric layer which is formed by the anodisation process can be optimised to more effectively passivate the underlying photoactive material and thus enable increased energy conversion performance from the final device

The patterned dielectric layer formed during the anodisation process can also be used as a mask through which a solid-state diffusion process can be performed. So, for example, a boron diffusion can be performed through the patterned dielectric layer formed over a p-type silicon wafer surface to create heavily-doped p+ regions at the bases of the holes. These heavily-doped regions may further reduce surface recombination by effectively creating a back surface field (BSF). In addition, contact resistance may also be reduced, resulting in more efficient carrier collection from the solar cell.

This process of forming point metal contacts to a solar cell has advantages over existing point contacting schemes where individual point contacts must be separately and deliberately patterned. Using the latter schemes, implemented using laser or inkjet/aerosol jet printer patterning, it is difficult to form small (<10 μm diameter) holes in a cost-effective way that maintains high through-put processing.

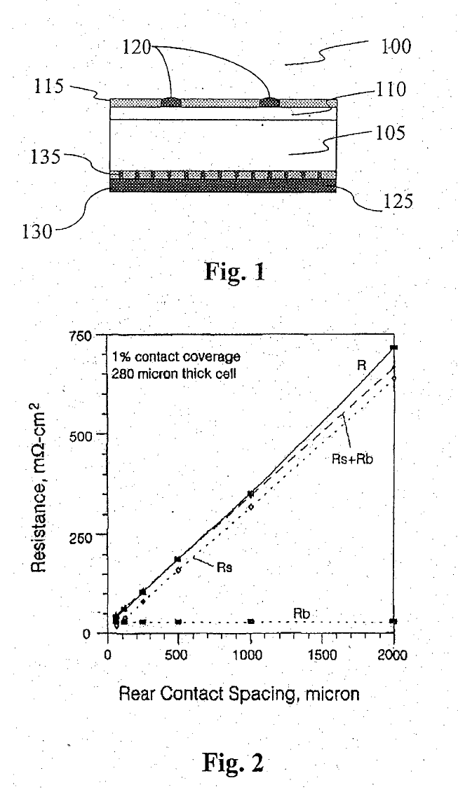

An arrangement of a solar cell rear contact and its formation will now be described in detail with reference to the accompanying drawings. FIG. 1 shows a cross-section of a typical crystalline silicon solar cell device 100. The cell comprises a p-type wafer substrate 105 of resistivity of 1-30 Ωcm with an n-type emitter layer 110, which has been preferably formed by performing a phosphorus diffusion on the surface of the wafer designed to be exposed to light. The thus-formed p-n junction enables electron and hole carriers that are generated by the absorption of light by the silicon to be separated and made available for collection at the electrodes of the solar cell.

After formation of the junction, typically a rear-surface etch procedure is performed using an in-line wet chemistry processing tool, such as provided by equipment manufacturers such as Rena, Schmid and Kuttler, to etch away any phosphorus-doped silicon on the rear surface and to edge-isolate the cell. An antireflection coating (ARC) 115 is then formed on the front surface of the cell to maximise the capture of light inside the cell. Most industrially produced silicon solar cells employ silicon nitride as the material for the ARC due to the suitability of its refractive index ( 2.0) and its relatively low temperature deposition ( 400° C.) using plasma-enhanced chemical vapour deposition (PECVD). However in some circumstances a silicon dioxide ARC may be preferred. The silicon nitride ARC also serves to passivate the n-type silicon wafer surface. It does this in two main ways. First, it can passivate dangling bonds that are present at the silicon surface thus reducing the concentration of defects at the surface which can result in high surface recombination. Second, positive charges present in the deposited silicon nitride layer repel the minority carriers from the silicon surface thus reducing the probability of recombination events close to the surface. The latter effect is called field effect passivation and is a technique that is routinely used in silicon solar cell fabrication to minimise the high surface recombination velocities that typically characterise metal-silicon interfaces and limit device performance.

Most industrially produced silicon solar cells then typically have a layer of aluminium paste screen printed on the rear surface and a front grid of silver paste screen printed over the ARC 115. The wafers are then briefly fired in an inline furnace at temperatures between 780 and 870° C., depending on the properties of the screen-printing pastes used. During this firing process, the aluminium diffuses into the rear surface silicon to form an aluminium-doped (p+) layer between the p-type silicon and the aluminium which forms a back surface field (BSF). This BSF layer repels the electron minority carriers from the rear aluminium electrode and hence reduces recombination at that surface. The silver paste, on being fired, penetrates the silicon nitride ARC and makes ohmic contact to the underlying n-type silicon layer to form the n-type electrode/s 120 for the solar cell.

However, it is well understood that the current industrial process of forming the rear aluminium electrode remains a significant source of efficiency loss due to the large silicon-metal interface area which limits the open circuit voltages of final devices to 620-630 mV. Industrially-fabricated screen-printed silicon solar cells typically are limited to energy conversion efficiencies in the range of 16-18%. Efficiencies of up to 25% have however been reported for laboratory-fabricated cells, such as the PERL cell, where fabrication techniques such as photolithography have been used to pattern point openings in a rear surface to enable small-area point metal contacts. These point contacts can limit the silicon-metal interface area to approximately 1% of the total rear cell area, which can result in a significant performance improvement as long as the remaining rear surface remains well passivated (i.e., has low surface recombination velocities).

Referring to the arrangement of FIG. 1, the rear contact is formed as described in greater detail below, by forming an aluminium layer and anodising it to form a porous oxide layer 125 in which the pores 135 provide intermittent connection points for the rear surface of the substrate 105. A further metal (aluminium) layer 130 is then evaporated onto the porous oxide layer 125 and extending through the pores 135 to contact the base of the cell. The metal contacts on the front surface can be formed substantially as described for industrially produced screen-printed cells or using one of a number of different selective-emitter technologies.

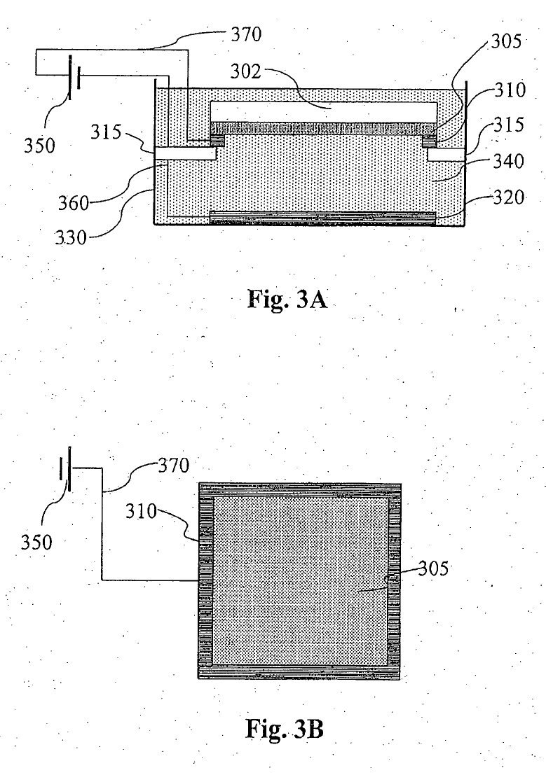

Unlike photolithography, the rear contact scheme described in this disclosure has the potential to be implemented at relatively low-cost and at high throughput. Furthermore it has the potential to result in very small openings which are spaced close together. The latter property is desirable if spreading resistance effects are to be minimised for the solar cell. FIG. 2 shows how the spreading (series) resistance reduces as the contacts are spaced more closely together on the rear surface. The optimum spacing is determined by the bulk resistivity of the silicon wafer and for wafers having a bulk resistivity of 1 Ωcm reductions in series resistance can be achieved down to a spacing of approximately 100 μm if a constant metal contact area of 1% is assumed. Unlike laser and inkjet patterning techniques which would become cumbersomely slow when required to pattern at this very fine resolution, the current self-patterning approach can achieve fine scale without significantly adversely affecting the speed of process. By effectively controlling the anodisation conditions, opening (pore) sizes and spacing can be controlled without having to individually pattern each required opening.

Anodisation is the electrolytic oxidation of a metal. It is typically used to form protective oxide layers on metals such as aluminium such that they will be resistant to chemicals and corrosion. The metal oxide is formed by making the metal part to be anodised the anode in an electrolytic bath which comprises an acid solution. The cathode can be an inert metal and the reduction reaction occurring at that electrode is typically the reduction of hydrogen ions to hydrogen gas.

For metals, such as aluminium, which have oxides that are soluble in the electrolyte, a balance occurs between formation and dissolution of the metal oxide. This balance results in the formation of a porous oxide (anodic) film. This film can accept or trap any material into its pores, either advantageous or disadvantageous to its properties. Consequently for metal barrier formation, the pores are typically closed or, “sealed” by addition of a hydrolysing solution which swells and in so doing closes off the pores and results in a smooth, hard, homogenous and transparent barrier layer. This sealing process may be carried out in boiling water, or in chemically-enriched water at room temperature. Dyes have also been used to provide decorative anodised surface with the dyes being introduced into the pore before sealing.

A range of acids can be used in order to achieve different anodisation results. For example, a sulphuric acid electrolyte typically results in soft, easily-dyed coatings whereas organic acids (e.g., oxalic acid) result in hard integral coatings. The temperature of the electrolyte can also be controlled to result in desirable properties. For example, at 20° C. a sulphuric acid electrolyte will result in a soft, transparent clear, easily-dyed coating whereas at 5° C. a hard, dense, dull grey coating results. In the arrangements described in this disclosure, the electrolyte composition is used to control the spacing and size of the formed pores in an aluminium layer formed on the rear silicon surface of the solar cell.

FIG. 5 schematically depicts an anodic aluminium oxide layer 120 in which pores 405 extend from the surface towards the silicon comprising the solar cell 420. At the base of the pores remains a barrier layer of aluminium oxide 410 which has chemically different properties from the aluminium oxide which forms at the walls of the pores.

An arrangement for forming this new rear contacting scheme will now be described with reference to FIGS. 3a & 3b. A layer of aluminium 305 is deposited on the rear silicon surface of the solar cell 302. The metal is preferably deposited using a thermal evaporation process though other deposition methods such as sputtering can also be used The thickness of the layer is preferably in the range of 0.2-1.0 μm, and more preferably between 0.3 and 0.7 μm. The deposited aluminium 305 is then preferably sintered for 30 minutes at 400° C. in order to reduce the granularity and decrease the porosity of the metal layer.

Before anodisation of the aluminium layer 305 of the solar cell 302, it may be necessary to remove a native aluminium oxide that may have formed over the metal layer. Preferably this is achieved by immersion in either 1-5% hydrofluoric acid or a commercially-available buffered oxide etching solution, such as provided by J. T. Baker. Alternatively, an etching recipe which etches aluminium oxide more readily than materials commonly used to form the ARC for the solar cell 302 (i.e., silicon nitride and silicon dioxide) can be used Such etching recipes include pad-etch solutions (described in Williams, K. R, Gupta, K and Waslik, M. (2003) Etch rates for micromachining processing Part 2, J. Microelectromech. Sys., 12, 761-778) or anhydrous ammonium fluoride solution (e.g., such as those formulated using a polyhydric alcohol such as ethylene glycol).

The solar cell 302 with the rear layer of aluminium 305 is then supported around its edges on an anode 310 which preferably has a centre opening slightly smaller than the cell being processed so that the aluminium layer on the rear surface of the cell is in contact with the anode around its entire periphery. The anode 310 is preferably made from an inert material such as platinum or palladium. This anode 310 is then connected via an insulated wire 370 to the positive terminal of a power source 350. The negative terminal of the power source 350 is connected via an insulated wire 360 to a cathode 320 which is placed in the base of the electrolysis cell 330. The cathode 320 can be composed of a metal such as nickel, aluminium or any other electrode which can support the required cathode reactions.

The annular anode 310 may be supported in the electrolysis cell 330 on a rim 315, constructed preferably from an acid resistant material such a polypropylene, which extends out from the sides of the cell 330. The annular anode 310 can be supported at an adjustable height above the cathode by adjusting the height of the rim 315 in the electrolysis cell 330. Preferably the distance between the cathode 320 and aluminium rear surface layer 305 is maintained between 2 and 5 cm in order to minimise resistive losses of the electrolyte 340. FIG. 3B shows the arrangement of the annular anode 310 when viewed from below the solar cell 302. The rim 315 is not included in this figure for purposes of clarity.

The arrangement depicted in FIG. 3A and FIG. 3B can also be implemented in an inline conveyor belt arrangement where solar cells 302 can be placed on an array of peripheral edge electrodes 310 that are connected to the conveying unit and transported through a bath or container containing the electrolyte 340. The cathode 320 can comprise a single strip electrode fixed to the bottom surface of the container. In this in-line arrangement, the movement of the individual solar cell and anode units can provide stirring of the solution which is advantageous for uniform anodisation. A means for applying downward pressure may be required to ensure that the solar cells 302 remain in electrical contact with the annular anode units 310. The downward pressure can be provided by a physical support that presses down on the lop surface of the solar cell 302. Preferably this support will be fabricated using a material such as Teflon which does not damage the ARC surface of the solar cell. Alternatively electrical contact of the solar cells 302 to the anode units 310 can be ensured by application of a fluid pressure, such as provided by a controlled flow of the electrolyte over the front surface of the solar cell or vacuum removal of the electrolyte substantially from below the aluminium surface 310 of the solar cell 302.

In a further variation, electrical connection to the rear aluminium layer of the solar cells 302 can be formed by a clip extending down into the electrolyte from a conveying belt substantially as described for use in electroplating systems provided by companies like Meco. In this arrangement, the solar cells 302 are transported through an anodisation bath due to the conveying motion of the overhead belt. Use of existing electroplating equipment (with reversed applied potential) provides a straightforward way of performing the anodisation step at high processing throughputs:

Once the solar cell 302 with the rear surface layer of aluminium 305 is supported on the annular anode unit 310, then the anodisation process can be started by using the power supply 350 to provide the necessary voltage for the anodisation process. Preferably the electrolyte comprises 0.1 to 1.5M sulphuric acid, and more preferably 0.3 M and an applied voltage of 8 to 30V. The anodisation time depends on the thickness of the aluminium layer 305, with a 500 nm layer of aluminium requiring 10 mins for complete oxidation in an electrolyte concentration of 0.3M sulphuric acid and applied voltage of 25V. The definition of the resulting pores in the anodised aluminium rear surface 305 of the solar cell 302 will depend upon the time exposed to the anodising process. The pores will be more distinctly formed after the longer anodisation times with times in the order of 10 to 60 mins being used depending also on the thickness of the aluminium layer to be anodised. The size and spacing of the pores depends on the electrolyte 340 used during the anodisation process. Table 1 below, lists typical size and spacings of pores for a range of different electrolyte solutions. By using a mixture of sulphuric acid and oxalic acid the interpore spacing and pore diameter can be increased to 150 nm and 70 nm, respectively.

TABLE 1
Typical size and spacings of pores for a range of different electrolyte
solutions anodized for 60 mins.

| | Interpore | Pore |
|---|---|---|
| Electrolyte | Distance (nm) | Diameter (nm) |
| 1. Sulphuric acid (0.3M) | 66.3 | 24 |
| 2. Sulphuric acid (1.2M) | 15 | 10 |
| 3. Oxalic acid (0.3M) | 105 | 31 |
| 4. Oxalic acid (0.3M) and | 150 | 69 |
| Sulphuric acid (0.3M) | | |

The pore spacing can be even further increased to a value of ˜500 nm by using other electrolytes such as phosphoric acid. Alternatively the aluminium layer 305 can be pre-patterned to initiate the formation of pores at a desired spacing. Pre-patterning can be achieved using an imprint method, such as nano or micro imprinting where a mould with the correct spacing is first formed and then pressed against the aluminium surface to slightly imprint the surface. Alternatively, a device such as an inkjet printer can be used to deposit a fluid which marks, or slightly etches, the aluminium surface at the points where it is desirable for pores to be initiated. This latter pre-patterning of the aluminium surface can be achieved by depositing an alkaline solution or phosphoric acid. Preferably these solutions are heated before deposition or the solutions are deposited on a heated aluminium surface. With this approach the spacing between pores can be controlled more tightly by predisposing the anodized aluminium to form pores in a predetermined pattern during the anodising process.

Under some circumstances, counter ions become trapped in the aluminium oxide porous matrix during the anodisation process. The presence of trapped anions, such as sulphate ions, is beneficial because they can provide field-effect passivation of the underlying p-type silicon. The presence of an electric field caused by the anions in the oxide film results in the depletion of (electron) minority carrier at the silicon aluminium oxide interface and thus reduces the surface recombination velocity. The effect of the electric field caused by the trapped charges in the anodic aluminium oxide field can be enhanced by causing the anions to migrate to the silicon-oxide interface such as by illuminating the solar cell 302 during the anodisation step. Illumination results in a light-induced potential forming across the solar cell 302 that can drive the diffusion of trapped anions close the silicon interface. For a typical crystalline silicon solar cell this potential is approximately 600 mV (i.e., the open circuit voltage of the solar cell).

The type and charge of the ions that can be trapped in the AAO layer can vary depending on electrolyte and illumination conditions. When the aluminium is anodised in sulphuric acid, positive ions can become trapped close to the barrier layer which forms at the interface between the metal and negative ions become trapped at the interface between the electrolyte and the AAO layer. The positive ions trapped close to the barrier layer can result in the formation of a depletion or inversion region in the adjacent p-type silicon. Such charge distribution changes at the silicon interface can also reduce recombination by reducing majority carrier concentrations at the interface. High lifetimes are typically observed when dielectric layers, such as silicon nitride, which contain positive stored charges are formed over p-type surfaces. In other words, recombination at the p-type silicon surface can be effectively reduced by the formation of either accumulation, depletion or inversion space charge regions at the interface because each of these conditions limit the possibility of both electrons and holes being present at the surface. If the solar cell 302 is illuminated during anodisation, then the charge condition at the silicon interface can be' modulated by the photo-generated potential that exists over the cell.

On completion of the anodisation process, the wafer is may be subjected to an aluminium oxide etching process which serves to: (i) remove a barrier layer of aluminium oxide which remains,at the silicon interface after anodisation; and (ii) widen the pores such that when they are metallised there is a sufficient cross-section of metal to ensure a low-resistance current collection path. This etching can be performed by immersion in a solution comprising 5% (w/v) phosphoric acid at room temperature for 1 to 5 mins and more preferably for 2 mins. Alternatively, an etching recipe such as described previously for the preferential etching of aluminium oxide can used so that the solar cell's ARC is not etched, and thus thinned, in the process. Preferably the etching is performed until the pores are between 200 and 250 nm in diameter and more preferably about 500 nm in diameter.

Finally, a metal such as aluminium can be deposited over the entire rear surface of the solar cell 302 using a line-of-sight deposition method such as thermal evaporation. Alternatively, the metal can be deposited using methods such as sputtering, e-beam evaporation or screen printing. Deposited aluminium will fill the pores in the insulating aluminium oxide layer and then extend over the entire rear surface as shown in FIG. 1 to form the rear p-type electrode for the solar cell 302. Preferably the thickness of the final aluminium metal layer is in the range: of 1-4 μm and more preferably 1-2 μm. After deposition the deposited aluminium is preferably sintered at 400° C. for 10 to 15 mins to ensure that the metal contacts through any oxide that may remain at the base of the pores. Alternatively, a higher temperature and a longer sintering time can be used to form an aluminium (i.e., p-type) region at the base of the pores. If a temperature which is higher than the aluminium-silicon eutectic temperature (577° C.) is used then an aluminium-silicon alloy can form at the base of the pores and thus enable low contact resistance at the metal silicon interface and hence lower device series resistance.

Other metals such as silver, tin and nickel can also be used although these metals do not provide the advantage of potential p+ doping through the pores. The use of aluminium as the rear contact metal is also desirable from the perspective of low final device cost.

The rear contacts can be formed using other metallisation approaches such as metal plating. Metals such as nickel, copper, tin and silver can be electrolessly plated or electroplated to both p- and n-type silicon. Once plating is initiated at the base of the openings, metal will continue to plate through the openings until the surface is reached, where the metal then starts to spread laterally over the rear dielectric surface to form a full metal contacted area on the rear of the cell.

In alternative arrangements metal contact to heavily-doped p-type silicon can be achieved by exposing the solar cell 302 (after anodisation) to a source of boron dopant atoms (e.g., boron tribromide) prior to the final metallisation step. If such a diffusion process is required then it is preferable for the solar cell. 302 to have been fabricated with a silicon dioxide ARC which can then mask the front n-type silicon surface from exposure to boron dopants. In a further alternative arrangement, the entire rear surface of the solar cell 302 could be exposed to p-type dopants (e.g., aluminium or boron), before the anodisation step to ensure the formation of a BSF across the entire rear surface. Metal subsequently deposited or plated through the openings would then contact heavily-doped silicon and hence metal contacts of lower contact resistance would result.

### Intervening Dielectric Layer

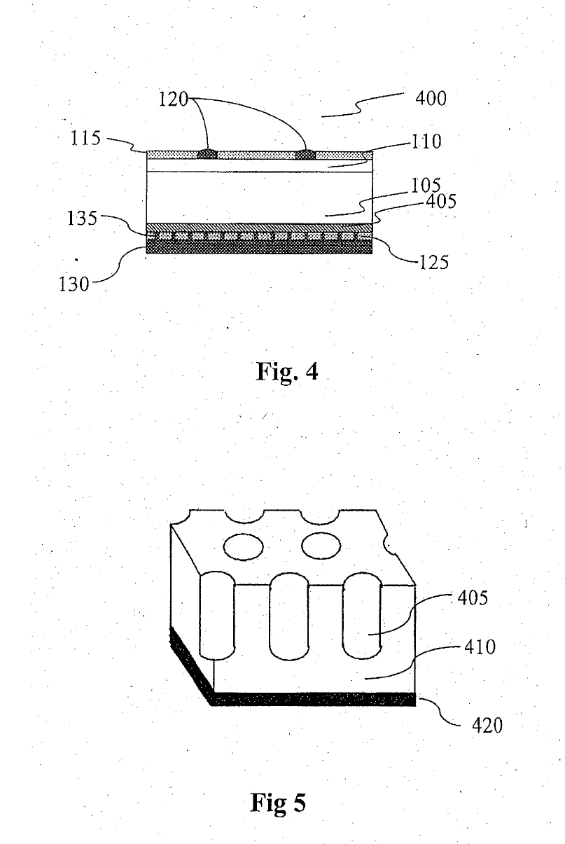

In a further embodiment an improved rear contact arrangement is achieved by forming an intervening thin dielectric layer between the rear silicon surface and the anodised aluminium layer. By inserting a dielectric layer of silicon dioxide, silicon carbide, silicon nitride and/or silicon oxynitride (or not removing an existing layer) between the rear silicon surface and the anodised aluminium layer 405, as illustrated in the device 400 shown in FIG. 4, the lifetime and implied open circuit voltage of solar cells can be improved over that achievable when only the intervening dielectric layer 405 is used The use of an intervening dielectric layer 405 can also help limit the anodisation to the aluminium layer on the rear surface of the wafer. This means that the endpoint of the anodisation process does not need to be controlled as carefully. Other dielectric materials (e.g., silicon carbide, PECVD deposited or sputtered aluminium oxide, amorphous silicon) can also be used in the formation of this intervening layer 405. For example, thin amorphous silicon layers can provide excellent surface passivation for crystalline silicon surfaces.

The formation of the AAO over these intervening dielectric layers has the potential to reduce recombination in final solar cell devices. The thickness of the intervening dielectric layer is preferably in the range of 10-85 nm but layer thickness of up to 150 nm can be used In this further embodiment the thickness of the anodised aluminium oxide layers is preferably 300 nm but thicknesses in the range of 200-800 nm can also be used.

An intervening silicon dioxide layer can be thermally-grown after the rear surface edge isolation step described above. The oxide layer is grown over both surfaces during this process and the thickness of the resulting silicon dioxide layer is controlled by the length of the oxidation process. Preferably a dry oxidation process is used to ensure a low surface recombination velocity interface between the silicon and silicon dioxide interface. However, a more rapid wet oxidation process can also be used. Preferably the oxide layer is then removed from the front surface of the cell and replaced with a silicon nitride layer (preferred ARC) which is deposited by PECVD as described for the preferred arrangement. Alternatively the front-surface oxide can be retained as a rudimentary ARC.

An intervening silicon nitride, silicon carbide, silicon oxide, silicon oxynitride, aluminium oxide layer can be deposited using PECVD over the rear silicon surface after the rear-surface etch step described above. Preferably, the deposition properties of these rear intervening dielectric layers are not substantially altered from those used to deposit a front surface silicon nitride ARC. After deposition, wafers are preferably subjected to a forming gas anneal (4% H₂ in Ar) for ˜15 minutes at a temperature of 350 to 500° C. and more preferably 400° C. to facilitate the diffusion of hydrogen from the PECVD layer into the wafer. Even higher temperature anneals (e.g., up to 720° C.) can be performed in a belt furnace but using times of less than 10 seconds at peak temperature. Wafers can also be annealed in nitrogen ambient and using forming gas mixtures where nitrogen replaces the more expensive argon.

Amorphous silicon layers can also be employed as the material for the intervening dielectric layer 405. Preferably amorphous silicon is deposited using PECVD and the thickness of such layers is preferably 40 to 80 nm and more preferably 60 nm.

After formation of the rear surface dielectric layer 405, wafers are cleaned in piranha solution (3:1 solution of 97% sulphuric acid and 30% (w/v) hydrogen peroxide), and then immersed in a 1%-5% HF solution for 1 min. Aluminium is then deposited onto the rear dielectric surface and anodised as described previously. The endpoint of the anodisation is detected by a drop in anodisation current, indicating that the metal layer is completely converted to aluminium oxide. This clear indication of anodisation enables the process to be carefully controlled and modifications to the anodisation process can be made without the requirement for calibration of the anodisation time.

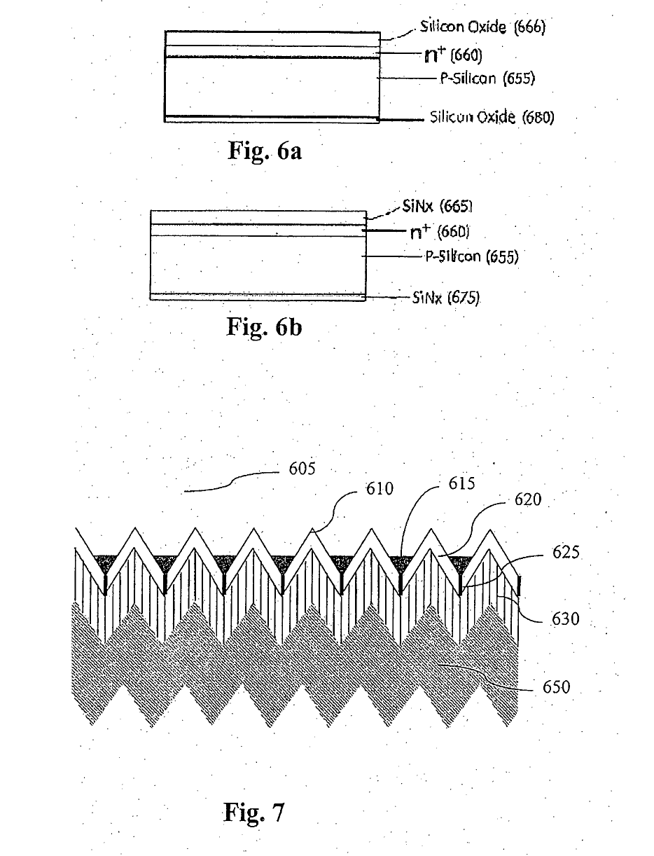

The passivation properties of the AAO dielectric stack comprising the intervening dielectric layer 405 and the formed AAO 125 can be compared with that achieved using just the intervening dielectric layer using a set of test structures shown in FIGS. 6a & 6b. These were formed using commercial-grade p-type 3 Ohm·cm boron-doped CZ wafers that were etched to remove surface saw damage (i.e., not textured). The test structures were phosphorus-diffused to form a lightly-doped front surface emitter as described above.

FIG. 6a diagrammatically illustrates a test structure having tri n⁺front surface layer 660 and a silicon oxide ARC layer 666 on a p-type silicon wafer 655. The rear dielectric structure depicted in FIG. 6a has a thermally-grown silicon dioxide layer 680 in contact with the rear surface of the silicon 655. This silicon dioxide layer 680 can be formed by using a thermal oxidation process to first grow an oxide on both surfaces to a thickness of 500 nm and then thinning the rear surface layer to a thickness between 10 to 140 nm, and more preferably to 60 nm. FIG. 6b also diagrammatically illustrates a test structure having an n⁺front surface layer 660. For the test structure shown in FIG. 6b, a 75 nm layer of silicon nitride 665 was deposited on the front surface of the wafer and another 75 nm layer of silicon nitride 675 was deposited on the rear surface of the wafer by PECVD, followed by a forming gas anneal (4% H₂ in Ar) for 15 minutes at a temperature of 400° C. The effective minority carrier lifetime of each of the test structures (FIGS. 6a & 6b) with and without a formed AAO was measured using photoconductance decay. The difference in the measured effective lifetime was then taken as a measure of the effectiveness of the AAO in reducing recombination in the test structure.

Table 2 shows the improvement in lifetime and implied open circuit voltage that can result when an AAO layer is formed over an intervening silicon dioxide layer. Both test structures measured demonstrate ˜60% increase in minority carrier lifetime with anodisation and an implied open circuit voltage of 670mV is measured. Table 3 shows the improvement in lifetime and implied open circuit voltage that can result when an AAO, layer is formed over an intervening silicon nitride layer. An implied open circuit voltage value of 717mV was measured for test structures having an intervening silicon nitride layer. These results, using the test structures depicted in FIGS. 6a & 6b, illustrate that a rear AAO layer can significantly improve surface passivation.

TABLE 2
Photoconductance decay measurements of test structures passivated
using an intervening layer of silicon dioxide (i.e., as shown in FIG. 6a)
before and after anodisation.

| | Sample 1 | | Sample 2 | |
|---|---|---|---|---|
| | | Impl V_{oc} | | Impl V_{oc} |
| Processing step | Lifetime (μs) | (mV) | Lifetime (μs) | (mV) |
| After diffusion and | 58 | 654 | 59 | 655 |
| growth of 500 nm | | | | |
| silicon dioxide layer | | | | |
| After thinning rear | 60 | 655 | 59 | 654 |
| oxide to 140 nm | | | | |
| After AAO | 105 | 672 | 104 | 671 |

TABLE 3
Photoconductance decay measurements of test structures passivated
using an intervening layer of silicon nitride (i.e., as shown in FIG. 6b)
before and after anodisation.

| | Sample 1 | | Sample 2 | |
|---|---|---|---|---|
| | | Impl V_{oc} | | Impl V_{oc} |
| Processing step | Lifetime (us) | (mV) | Lifetime (us) | (mV) |
| After silicon nitride | 186 | 683 | 256 | 668 |
| deposition | | | | |
| After anneal | 661 | 673 | 678 | 705 |
| After AAO | 726 | 728 | 976 | 721 |

Metallisation through the Dielectric Layer

Use of the intervening dielectric layer enables an alternative form of metal contacting. Rather than forming metal contacts at the bases of individual pores of the AAO layer as described above, aluminium deposited over the surface of the AAO can be fired in a way that the aluminium only permeates the dielectric layer at the pyramid peaks or ridges of a textured silicon wafer. Preferably the texturing depth is in the range of 1-5 μm but textures with features as large as 10 μm can also be used.

Preferably, firing of the rear aluthinium layer is performed at between 650° and 820° C. and more preferably at 680° C. for less than 10 seconds at the peak temperature using an industrial belt furnace. The temperature needs to be sufficiently high to ensure that the aluminium permeates the dielectric structure but only at the pyramid peaks or ridges. Use of excessive temperatures or long firing times will result in larger than desirable metal coverage areas. Firing the aluthinium after the pores have been filled with metal drives the aluminium through the intervening dielectric layer. In the case of a textured surface the aluminium is selectively driven through the dielectric at the peaks or ridges (highest points) of the texturing.

A further advantage of metal contacting through just the peaks or ridges of the pyramids is that the metal to silicon contact area can be reduced from that which is typical if the metal contacts the silicon at the bottom of all the pores (which is estimated to be ˜10% of the area of the anodized aluminium). With the inclusion of a dielectric layer in the contacting scheme and by limiting the metal contact area to the peaks or ridges, the contact area can be in the range of 1-2% of the area of the anodized aluminium layer on a textured surface. Furthermore the process of firing the metal through the intervening dielectric layer will form p+ regions in the contact regions enabling ohmic contact between the aluminium layer that is evaporated over the entire rear surface and the silicon solar cell.

This method of contacting the silicon via raised areas of the textured surface is possible with both alkaline (pyramid-based) textures forming peaks and acidic (concavity-based) textures forming ridges. FIG. 7 depicts an example of the metal contacting scheme for alkaline-textured surface. In FIG. 7, a p-type silicon wafer 605 has an alkaline textured rear surface 610, an evaporated metal (e.g. aluminium) layer 650, an intervening rear dielectric layer 620, AAO layer with pores filled with metal (e:g. aluminium) 630, metal penetration through the dielectric layer at the textured peaks 625 (or ridges) and a p+region formed by the firing of the metal through the intervening dielectric layer 615.

In a further variation of this approach of metal contacting, screen printed aluminium paste can be used in the place of evaporated or sputtered aluminium films. Use of such screen-printed paste is commonplace in the manufacture of silicon solar cells and hence is readily-available and can be fired at the temperatures described above.

The examples given are for a device based on a p type silicon wafer with n-type doping on the front (illuminated) surface. However it will be recognised that a device based on an n type wafer might also be considered in which case it would be necessary to use n type dopants such as phosphorus in the doping step to heavily dope the rear surface or those portions of the rear surface under the openings in the porous metal-oxide layer.

It will be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive and in particular new combinations of features may be created by combining selected feature and methods of the various exemplified embodiments without departing from the spirit of the invention.

1-3. (canceled)

4. A method of forming point metal electrical contacts to a semiconductor surface of a semiconductor device, the method comprising:
i) forming a dielectric layer on the semiconductor surface:
ii) forming a first metal layer over the dielectric layer;
iii) anodising the first metal layer to create a porous metal-oxide layer formed over the dielectric layer whereby pores in the porous metal-oxide layer form an array of openings in the porous metal-oxide layer;
iv) forming a metal contact layer over the porous metal-oxide layer; and
v) heating the metal contact layer such that parts of the metal contact metal layer are driven through the dielectric layer to electrically contact the semiconductor surface through the array of openings in the porous metal-oxide layer and the dielectric layer.

5. The method of claim 3 wherein the dielectric layer comprises silicon dioxide, silicon nitride, silicon oxynitride, silicon carbide, aluminum oxide or a combination of two or more thereof.

6. The method of claim 1 wherein the dielectric layer thickness is in a range of 10-85 nm.

7-8. (canceled)

9. The method as claimed in claim 4 wherein the semiconductor surface is textured to a depth of 1-8 μm.

10. (canceled)

11. The method of claim 4 wherein the heating of the metal contact layer is controlled to limit contact of the contact metal layer with the semiconductor surface to occur only through those pores located at or adjacent to peaks or ridges of the texturing of the semiconductor surface.

12. The method as claimed in claim 4 wherein the first metal layer is a layer comprising aluminium or titanium.

13. (canceled)

14. The method as claimed in claim 4 wherein the porous metal-oxide layer is etched to enlarge the pores forming the array of openings through the porous metal-oxide layer prior to the formation of the contact metal layer.

15. The method as claimed in claim 4 wherein the porous metal-oxide layer is etched further before application of the metal contact layer to ensure that any barrier layer oxide is removed from the semiconductor surface at the base of the openings of the array of openings through the porous metal-oxide layer.

16. The method as claimed in claim 4 wherein the first metal layer is pre-processed to cause the pores which result from the anodising step to preferentially form in selected locations.

17-21. (canceled)

22. The method as claimed in claim 4 wherein the average pore spacing is less than 200 μm.

23. (canceled)

24. The method as claimed in claim 4 wherein the acid used in the anodisation process is selected from sulphuric acid, oxalic acid, phosphoric acid, or combinations of these used together or serially.

25-27. (canceled)

28. The method as claimed in claim 4 wherein the first metal layer is deposited by one of sputtering or a thermal evaporation process.

29-32. (canceled)

33. The method as claimed in claim 4 wherein the metal contact layer is deposited into the pores and over the entire surface of the porous metal-oxide layer using a method selected from sputtering, e-beam evaporation thermal evaporation screen printing or metal plating.

34. The method as claimed in claim 33 wherein, the metal contact layer is a layer of comprising aluminium.

35. The method as claimed in claim 4 wherein the metal contact layer is formed in the openings and of the porous metal-oxide layer by metal plating with one or more of nickel, copper, tin and/or silver.

36-41. (canceled)

42. The method as claimed claim 4 wherein the contact metal layer is sintered at a temperature higher than the metal-semiconductor eutectic temperature to diffuse the contact metal into the semiconductor surface such that a metal-semiconductor alloy is formed at the base of the pores.

43. (canceled)

44. The method as claimed in claim 4 wherein the step of heating of the contact metal layer comprises firing of the contact metal layer at a peak temperature in the range of 650°-820° C. or 650°-670° C. or 670°-690° C. or 690°-710° C. or 710°-730° C. or 730°-750° C. or 750°-770° C. or 770°-790° C. or 790°-810° C. or 810° to 820° C. for less than 60 seconds at the peak temperature.

45-50. (canceled)

51. A semiconductor device having a semiconductor surface on which an electrical contact is formed, the device comprising:
i) a dielectric layer formed over the semiconductor surface;
ii) a porous metal-oxide layer formed over the dielectric layer whereby pores in the porous metal-oxide layer form an array of openings through the porous metal-oxide layer;
iii) a metal contact layer located over the porous metal-oxide layer such that the metal contact layer electrically contacts the semiconductor surface through the array of openings in the porous metal-oxide layer and the dielectric layer to form the electrical contact.

52-53. (canceled)

54. The semiconductor device of claim 51, wherein the semiconductor surface is textured to a depth of 1-8 μm.

55-72. (canceled)

73. The semiconductor device as claimed in claim 51 wherein the metal contact layer is located in the openings and over the entire surface of the porous metal-oxide layer and comprises one or more of aluminum, nickel, copper, tin and/or silver.
